(19) United States
(12) Patent Application Publication
(10) Pub. No.: US 2013/0279968 A1
(43) Pub. Date: Oct. 24, 2013

(54) MOUNTING DEVICE FOR CIRCUIT BOARD

(71) Applicants: Hong Fu Jin Precision Industry (ShenZhen) Co., Ltd., (US); Hon Hai Precision Industry Co., Ltd., (US)

(72) Inventors: ZHAN-YANG LI, Shenzhen (CN); CHONG DUAN, Shenzhen (CN)

(73) Assignees: HON HAI PRECISION INDUSTRY CO., LTD., New Taipei (TW); HONG FU JIN PRECISION INDUSTRY (ShenZhen) CO., LTD, Shenzhen (CN)

(21) Appl. No.: 13/740,253

(22) Filed: Jan. 13, 2013

(30) Foreign Application Priority Data
Apr. 20, 2012 (CN) 201210117495.7

(51) Int. Cl. H05K 7/02

(52) U.S. Cl. CPC H05K 7/02
USPC 403/27

(57) ABSTRACT

A mounting device for securing a circuit board to a bottom plate of a chassis includes a positioning post, an installation member, a moving member, and a mounting member. The positioning post defines a groove. The moving member is slidably received in the installation member and includes a first driving portion. The mounting member is mounted to the installation member and prevents the moving member from sliding out of the installation member. The mounting member includes two resilient portions. The moving member is slidable relative to the mounting member. The first driving member elastically deforms the two resilient portions to be received in the groove when the moving member is slid towards the mounting member to secure the mounting member to the positioning post. The first driving portion is secured between the two resilient portions, to prevent the moving member from sliding relative to the mounting member.

### BACKGROUND

1. Technical Field

The present disclosure relates to mounting devices, and more particularly to a mounting device for a circuit board.

2. Description of Related Art

A motherboard of an electronic device chassis defines a plurality of first mounting holes, and a bottom plate of the electronic device chassis defines a plurality of second mounting holes. A plurality of screws is locked in the first and second mounting holes to secure the motherboard to the bottom plate. However, the alignment of the first mounting holes with the plurality of second mounting holes is time-consuming and inconvenient.

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of one embodiment of a mounting device, a bottom plate of an electronic device chassis, and a motherboard.

FIG. 2 is an assembled, isometric view of the mounting device, the bottom plate, and the motherboard of FIG. 1.

FIG. 3 is a cross-sectional view of the mounting device, the bottom plate, and the motherboard of FIG. 2, taken along a line III-III.

FIG. 4 is similar to FIG. 2, but shows the mounting device in a locked position.

FIG. 5 is a cross-sectional view of the mounting device, the bottom plate, and the motherboard of FIG. 4, taken along a line V-V.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

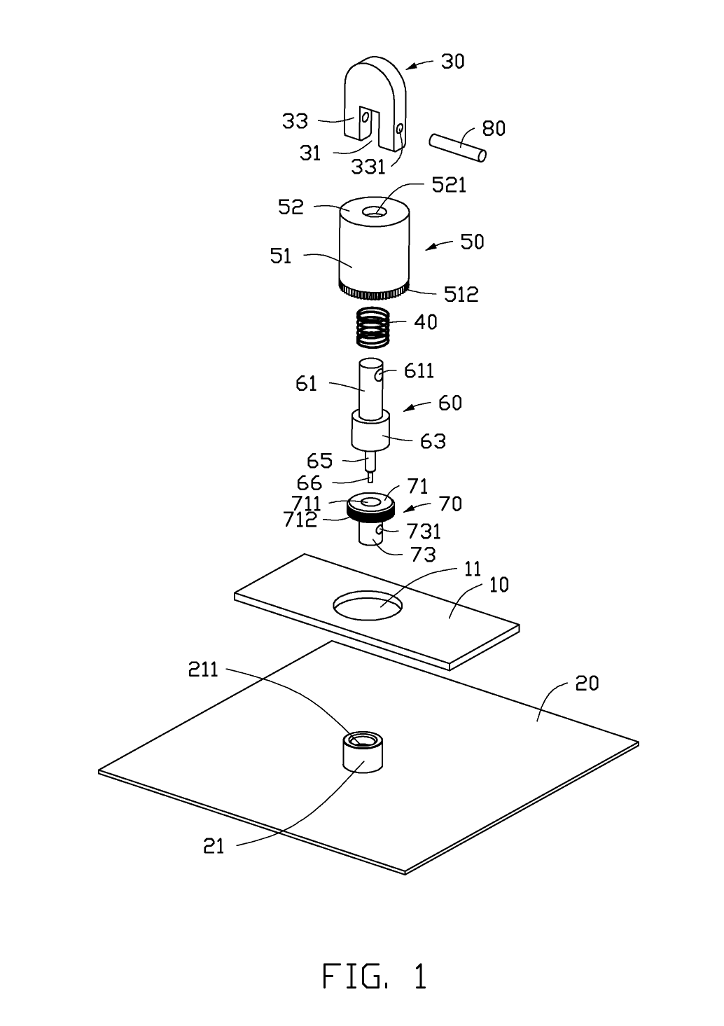

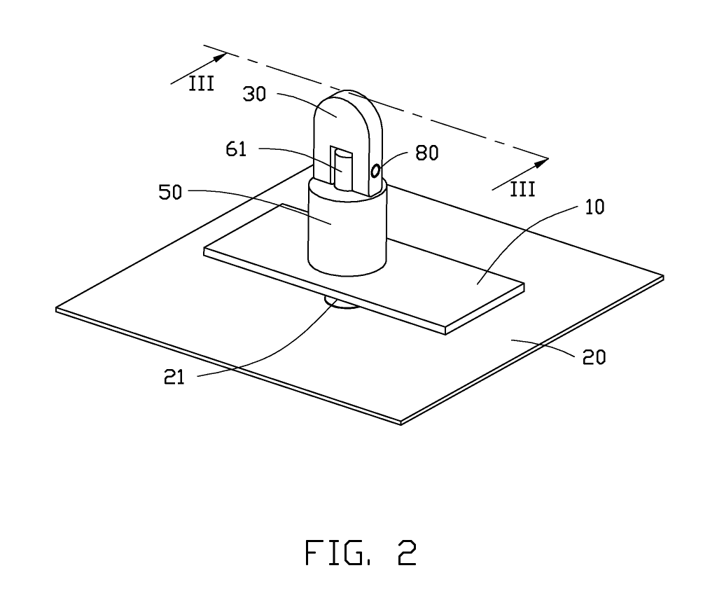

FIG. 1 illustrates one embodiment of a mounting device. The mounting device is used for securing a circuit board 10 to a bottom plate 20 of an electronic device chassis. The circuit board 10 defines a plurality of mounting holes 11. Only one mounting hole 11 is shown in FIGS. 1-5 as example. In one embodiment, the circuit board 10 is a motherboard, and the mounting hole 11 is substantially circular.

The mounting device includes a positioning post 21, an operation member 30, a resilient member 40, an installation member 50, a moving member 60, and a mounting member 70.

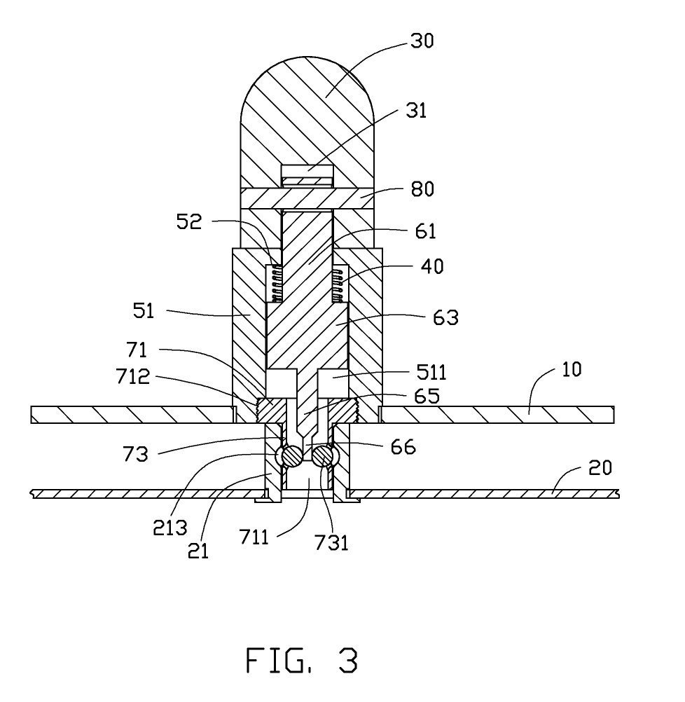

The positioning post 21 is removably secured to the bottom plate 20 and defines a plurality of positioning holes 211 corresponding to the plurality of mounting holes 11. The positioning post 21 further defines a ring groove 213 (shown in FIG. 3) in an inner surface of the positioning hole 211. In one embodiment, the positioning hole 211 is substantially circular.

FIG. 1 and FIG. 3 show that the operation member 30 defines a cutout 31, and two legs 33 are located on opposite sides of the cutout 31. Each leg 33 defines a through hole 331. The through hole 331 extends out of the leg 33 and communicates with the cutout 31.

The installation member 50 includes a body 51 and a top wall connected to the body 51. The body 51 defines an installation hole 511. The top wall 52 defines an opening 521. In one embodiment, each of the installation hole 511 and the opening 521 is substantially circular, the body 51 is a hollow cylinder, a diameter of the installation hole 511 is greater than that of the opening 521, and an outer diameter of the body 51 is substantially equal to a diameter of the mounting hole 11. The installation hole 511 defines a plurality of inner threads (not labeled). An outer surface of the body 51 defines a threaded portion 512.

The moving member 60 includes an installation portion 61, a moving portion 63, a first driving portion 65, and a second driving portion 66. The installation portion 61 and the first driving portion 65 extend from two opposite surfaces of the moving portion 63. The first driving portion 65 is located between the moving portion 63 and the second driving portion 66. In one embodiment, a cross-section of each of the installation portion 61, the moving portion 63, the first driving portion 65, and the second driving portion 66 is substantially circular, a diameter of the installation portion 61 is greater than the diameter of the opening 521 and a diameter of the moving portion 63, the diameter of the moving portion 63 is greater than the diameter of the opening 521 and smaller than the diameter of the installation hole 511. A diameter of the first driving portion 65 is greater than a diameter of the second driving portion 66 and smaller than the diameter of the moving portion 63. The installation portion 61 defines a pivoting hole 611.

In one embodiment, the resilient member 40 is an expansion spring.

The mounting member 70 includes a locking portion 71 and a mounting portion 73 extending from the locking portion 71. In one embodiment, a cross-section of each of the locking portion 71 and the mounting portion 73 is substantially circular, a diameter of the locking portion 71 is greater than a diameter of the mounting portion 73 and the diameter of the positioning hole 211, and the diameter of the mounting portion 73 is smaller than the diameter of the positioning hole 211. The locking portion 71 defines a mounting hole 711 and a plurality of outer threads 712. The mounting hole 711 extends out of the mounting portion 73. The mounting portion 73 comprises two opposite resilient portions 731. The two resilient portions 731 are elastically deformable along a horizontal direction. In one embodiment, a smallest distance between the two resilient portions 731 is substantially equal to the diameter of the second driving portion 66, and a maximum distance between the two resilient portions 731 is substantially equal to the diameter of the first driving portion 65.

FIG. 1 and FIG. 3 show that in assembly, the installation portion 61 is received in the resilient member 40. The moving member 60 is inserted in the installation hole 511, and the installation portion 61 extends out of the opening 521. A first end of the resilient member 40 abuts the top wall 52. A second end of the resilient member, opposite to the first end, abuts the moving portion 63. The operation member 30 is moved to abut the legs 33 to the top wall 52, and the installation portion 61 is received in the cutout 31. The through hole 331 is aligned with the pivoting hole 611. A shaft 80 is inserted into the through hole 331 and the pivoting hole 331, so that the operation member 30 is rotatably mounted to the moving member 60. In one embodiment, the shaft 80 is substantially parallel to the top wall 52. The mounting member 70 is placed under the installation member 50, and the locking portion 71 is aligned with the installation hole 511. The locking portion 71 is locked into the installation hole 511. Thus, the mounting member 70 is secured to the installation member 50 and prevents the moving portion 63 from sliding out of the installation hole 511. The first driving portion 65 and the second driving portion 66 are received in the mounting hole 711. In this position, the operation member 30 is substantially perpendicular to the top wall 52, and the resilient member 40 and the resilient portion 731 are located in an initial position, the resilient member 40 is received in the mounting portion 73, the operation member 30 is substantially perpendicular to the circuit board 10, and the second driving portion 66 is located between the two resilient portions 731. The smallest distance is defined between the two resilient portions 731, and a first distance is defined between the shaft 80 and the top wall 52. Thus, the mounting device is located in an unlocked position.

In use, the mounting device is moved to be adjacent to the circuit board 10, and the mounting portion 73 is inserted through the mounting hole 11. The threaded portion 512 is engaged in the mounting hole 11, and there is an interference fit between the threaded portion 512 and the mounting hole 11. Thus, the mounting device is secured to the circuit board 10, and the mounting device is located in the unlocked position.

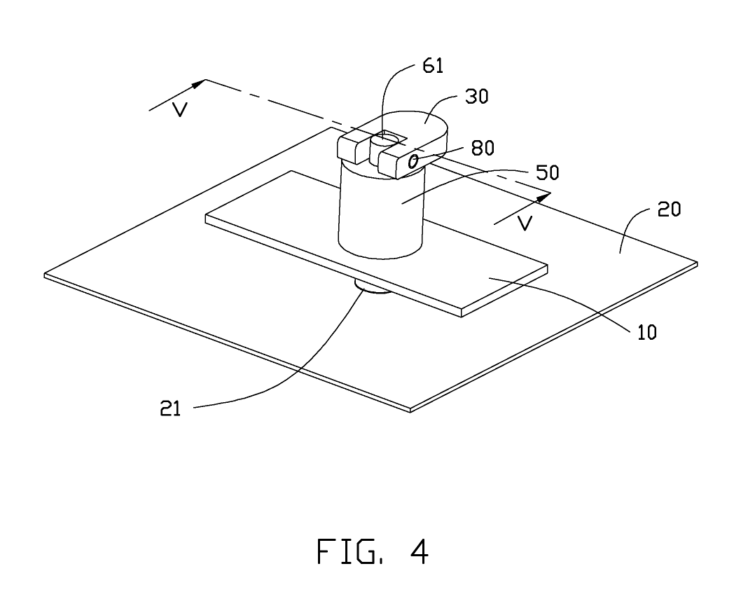

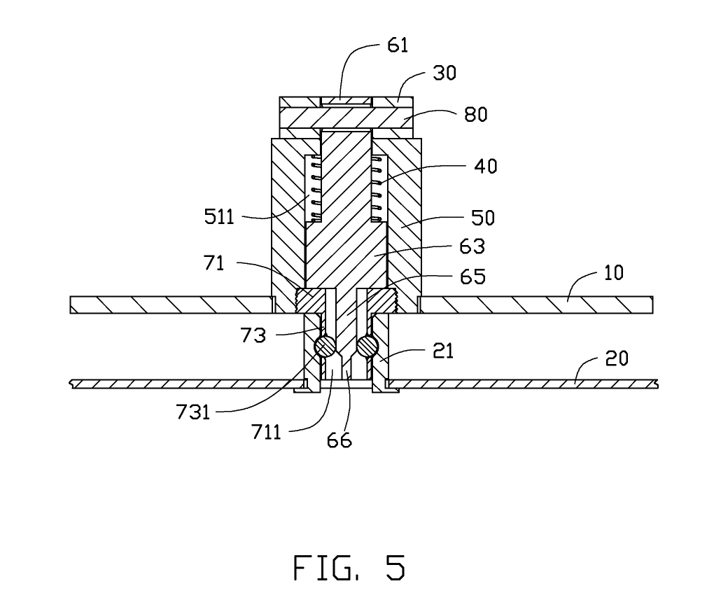

FIG. 4 and FIG. 5 show that in assembly of the circuit board 10, the circuit board 10 is moved to be adjacent to the bottom plate 20, and the mounting portion 73 is aligned with the positioning hole 211. The circuit board 10 is moved towards the circuit board 10, the mounting portion 73 is received in the positioning hole 211, and the two resilient portions 731 are aligned with the ring groove 213. The operation member 30 is rotated towards the bottom plate 20, the distance between the shaft 80 and the top wall 52 becomes smaller, and an elastic deformation of the resilient member 40 becomes larger. The second driving portion 66 slides over between the two resilient portions 731, the first driving portion 62 presses the two resilient portions 731 to elastically deform the two resilient portions 731. Until the operation member 30 is substantially parallel to the top wall 52 and the circuit board 10, and one side of the operation member 30 abuts the top wall 52, the moving portion 63 abuts the locking portion 71, the two resilient portions 731 protrude from the mounting portion 73 and are received in the ring groove 213, and the first driving portion 65 is sandwiched between the two resilient portions 731. A maximum distance is defined between the two resilient portions 731. A second distance is defined between the shaft 80 and the top wall 52. The second distance is smaller than the first distance. Thus, the mounting device is located in a locked position, and the mounting device secures the circuit board 10 to the bottom plate 20.

In disassembly, the operation member 30 is rotated away from the bottom plate 20. The resilient member 40 rebounds to slide the moving member 60 away from the bottom plate 20. The first driving portion 65 slides out of between the two resilient portions 731. The two resilient portions 731 rebound to disengage from the ring groove 213. Thus, the circuit board 10 can be removed from the bottom plate 20, and the mounting device is located in the unlocked position.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. A mounting device for securing a circuit board to a bottom plate of a chassis comprising:
a positioning post configured for being secured to the bottom plate and defining a groove;
an installation member configured for being secured to the circuit board;
a moving member slidably received in the installation member and comprising a first driving portion; and
a mounting member mounted to the installation member and preventing the moving member from sliding out of the installation member;
wherein the mounting member comprises two resilient portions; the moving member is slidable relative to the mounting member; the first driving member elastically deforms the two resilient portions to be received in the groove when the moving member is slid towards the mounting member to secure the mounting member to the positioning post; and the first driving portion is secured between the two resilient portions to prevent the moving member from sliding relative to the mounting member.

2. The mounting device of claim 1, wherein the installation member comprises a body and a top wall connected to the body, the body defines an installation hole, and the top wall defines an opening; the moving member further comprises a moving portion and an installation portion; the moving portion is slidably received in the installation hole; and the installation portion extends out of the opening.

3. The mounting device of claim 2, wherein the moving portion is located between the installation portion and the first driving portion.

4. The mounting device of claim 2, further comprising a resilient member, wherein the installation portion is engaged with the resilient member, and the resilient member is secured between the top wall and the installation portion.

5. The mounting device of claim 2, wherein the mounting member further comprises a locking portion and a mounting portion, and the mounting member defines a mounting hole; the locking portion is secured to the installation member; the two resilient portions are located on the mounting portion; and the first driving portion is received in the mounting hole.

6. The mounting device of claim 5, wherein the two resilient portions are received in the mounting hole, and the two resilient portions extend out of the mounting hole to the groove when the two resilient portions are elastically deformed.

7. The mounting device of claim 2, further comprising an operation member configured for sliding the moving member, wherein the operation member is rotatably mounted to the installation member about a shaft.

8. The mounting device of claim 7, wherein the operation member abuts the top wall and defines a cutout and a through hole; the installation portion defines a pivoting hole; the shaft is inserted into the through hole, the pivoting hole, and the cutout; and the shaft is substantially parallel to the top wall.

9. The mounting device of claim 8, wherein the shaft is movable relative to the installation member when the operation member is rotated about the shaft.

10. The mounting device of claim 8, wherein the operation member is rotatable to slide the moving member towards or away from the mounting member, and the first driving portion is disengaged from the two resilient portions when the moving member is slid towards the mounting member; and the two resilient portions rebound to disengage from the groove when the first driving portion is disengaged from the groove.

11. A mounting device for securing a circuit board to a bottom plate of a chassis comprising:
a positioning post configured for being secured to the bottom plate and defining a groove;
an installation member configured for being secured to the circuit board;
a moving member slidably received in the installation member and comprising a first driving portion;
a mounting member mounted to the installation member and preventing the moving member from sliding out of the installation member; and
an operation member rotatably mounted to the moving member;
wherein the mounting member comprises two resilient portions, the operation member is rotatable to the installation member to slide the moving member towards or away from the mounting member; the first driving member elastically deforms the two resilient portions to be received in the groove when the moving member is slid towards the mounting member to secure the mounting member to the positioning post; and the first driving portion is secured between the two resilient portions to prevent the moving member from sliding relative to the mounting member.

12. The mounting device of claim 11, wherein the installation member comprises a body and a top wall connected to the body, the body defines an installation hole, and the top wall defines an opening; the moving member further comprises a moving portion and an installation portion; the moving portion is slidably received in the installation hole; and the installation portion extends out of the opening.

13. The mounting device of claim 12, wherein the moving portion is located between the installation portion and the first driving portion.

14. The mounting device of claim 12, further comprising a resilient member, wherein the installation portion is received in the resilient member, and the resilient member is secured between the top wall and the installation portion.

15. The mounting device of claim 12, wherein the mounting member further comprises a locking portion and a mounting portion, and the mounting member defines a mounting hole; the locking portion is secured to the installation member; the two resilient portions are located on the mounting portion; and the first driving portion is received in the mounting hole.

16. The mounting device of claim 15, wherein the two resilient portions are received in the mounting hole, and the two resilient portions extend out of the mounting hole to the groove when the two resilient portions are elastically deformed.

17. The mounting device of claim 12, wherein the operation member is rotatably mounted to the installation member about a shaft.

18. The mounting device of claim 17, wherein the operation member abuts the top wall and defines a cutout and through hole; the installation portion defines a pivoting hole; the shaft is inserted into the through hole, the pivoting hole, and the cutout; and the shaft is substantially parallel to the top wall.

19. The mounting device of claim 18, wherein the shaft is movable relative to the installation member when the operation member is rotated about the shaft.

20. The mounting device of claim 18, wherein the first driving portion is disengaged from the two resilient portions when the moving member is slid towards the mounting member; and the two resilient portions rebound to disengage from the groove when the first driving portion is disengaged from the groove.
